(19) United States
(12) Patent Application Publication
(10) Pub. No.: US 2013/0242618 A1
(43) Pub. Date: Sep. 19, 2013

(54) COMPOUND SEMICONDUCTOR DEVICE AND METHOD FOR MANUFACTURING THE SAME

(71) Applicant: FUJITSU LIMITED, Kawasaki-shi (JP)

(72) Inventor: Atsushi YAMADA, Isehara (JP)

(21) Appl. No.: 13/720,349

(22) Filed: Dec. 19, 2012

(30) Foreign Application Priority Data
Mar. 19, 2012 (JP) 2012-062708

(51) Int. Cl. H01L 29/66; H02M 3/335; H01L 29/778

(52) U.S. Cl. CPC H01L 29/66431; H01L 29/778; H02M 3/335
USPC 363/17; 257/194; 438/172

(57) ABSTRACT

The AlGaN/GaN HEMT includes, on an SiC substrate, a laminated compound semiconductor structure and a gate electrode formed on the laminated compound semiconductor structure, wherein a p-type impurity (Mg) and oxygen (O) localize in a lower region of the laminated compound semiconductor structure aligned with the gate electrode, to such a depth as to cause part of a two-dimensional electron gas generated in the laminated compound semiconductor structure to disappear.

### CROSS-REFERENCE TO RELATED APPLICATION

This application is based upon and claims the benefit of priority of the prior Japanese Patent Application No. 2012-062708, filed on Mar. 19, 2012, the entire contents of which are incorporated herein by reference.

### FIELD

The embodiments described herein relate to a compound semiconductor device and a method for manufacturing the compound semiconductor device.

### BACKGROUND

A study is being made on the application of a nitride semiconductor to high-voltage resistance high-output semiconductor devices by taking advantage of the characteristic features of the nitride semiconductor, such as high saturated electron velocity, a wide bandgap and the like. For example, the bandgap of GaN which is a nitride semiconductor is 3.4 eV, higher than the bandgap (1.1 eV) of Si and the bandgap (1.4 eV) of GaAs, thus having high breakdown field strength. Accordingly, GaN holds great promise as a material of a semiconductor device for power supplies from which high-voltage operation and high output are available.

Many reports have been made of a field-effect transistor, a high electron mobility transistor (HEMT) in particular, as a device using a nitride semiconductor. For example, an AlGaN/GaN HEMT using GaN as an electron transit layer and AlGaN as an electron supply layer is a focus of attention as a GaN-based HEMT (GaN-HEMT). In the AlGaN/GaN HEMT, strain due to a difference in lattice constant between GaN and AlGaN arises in AlGaN. Piezoelectric polarization and the spontaneous polarization of AlGaN caused by this strain provide a high-concentration, two-dimensional electron gas (2DEG). Accordingly, the HEMT is expected for use as a high-efficiency switch element or a high-voltage resistance power device for electric vehicles and the like.
Patent Document 1: Japanese Laid-open Patent Publication No. 2009-76845
Patent Document 2: Japanese Laid-open Patent Publication No. 2007-19309

The nitride semiconductor device requires a technique of locally controlling the amount of generated 2DEG. In the case of, for example, a HEMT, so-called normally-off operation in which no currents flow when voltages are turned off is desired from a so-called fail-safe point of view. To that end, contrivances need to be made to suppress the amount of 2DEG generated underneath a gate electrode when voltages are turned off.

As one of methods for realizing a GaN HEMT for normally-off operation, there has been proposed a method in which a p-type GaN layer is formed on an electron supply layer to cancel out a 2DEG in a portion of the electron supply layer underneath the p-type GaN layer, thereby achieving normally-off operation. In this method, p-type GaN is grown on the entire surface of, for example, AlGaN to serve as the electron supply layer. Then, the p-type GaN is dry-etched and left over in a portion where a gate electrode is to be formed, thereby forming the p-type GaN layer. Then, the gate electrode is formed on the p-type GaN layer.

In this case, however, the p-type dopant of the p-type GaN layer diffuses through the electron supply layer as far as into an electron transit layer underneath the electron supply layer when the p-type GaN layer is grown. Since the 2DEG is generated in an interfacial boundary of the electron transit layer with the electron supply layer, the 2DEG disappears in whole due to the diffusion of the p-type dopant. Thereafter, the 2DEG is not recovered even if the p-type GaN is dry-etched and removed while leaving over portion where the gate electrode is formed, since the p-type dopant is diffused into the electron transit layer.

In addition, the electron supply layer present in a lower portion of the p-type GaN suffers etching damage due to the dry etching of the p-type GaN. This damage increases the resistance of the electron supply layer to make the recovery of the 2DEG even more difficult.

### SUMMARY

One aspect of a semiconductor device includes a laminated compound semiconductor structure and an electrode formed on the laminated compound semiconductor structure, wherein a p-type impurity localizes in a region of the laminated compound semiconductor structure aligned with the electrode, to such a depth as to cause part of a two-dimensional electron gas generated in the laminated compound semiconductor structure to disappear.

One aspect of a semiconductor device manufacturing method includes: forming a p-type impurity-doped compound layer in a region on a laminated compound semiconductor structure where an electrode is to be formed; and heat-treating the compound layer to diffuse the p-type impurity of the compound layer to such a depth as to cause part of a two-dimensional electron gas generated in the laminated compound semiconductor structure to disappear.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIGS. 1A to 1C are schematic cross-sectional views illustrating a method for manufacturing an AlGaN/GaN HEMT according to a first embodiment in the order of steps;

FIGS. 2A to 2C are schematic cross-sectional views illustrating the method for manufacturing the AlGaN/GaN HEMT according to the first embodiment in the order of steps following the steps of FIGS. 1A to 1C;

FIGS. 3A and 3B are schematic cross-sectional views illustrating the method for manufacturing the AlGaN/GaN HEMT according to the first embodiment in the order of steps following the steps of FIGS. 2A to 2C;

FIGS. 4A and 4B are schematic cross-sectional views illustrating the method for manufacturing the AlGaN/GaN HEMT according to the first embodiment in the order of steps following the steps of FIGS. 3A and 3B;

FIGS. 5A and 5B are schematic cross-sectional views illustrating main steps of a method for manufacturing an AlGaN/GaN HEMT according to a second embodiment;

FIG. 6 is a schematic plan view illustrating a HEMT chip using an AlGaN/GaN HEMT according to the first or second embodiment;

FIG. 7 is a schematic plan view illustrating a discrete package of the HEMT chip using the AlGaN/GaN HEMT according to the first or second embodiment;

FIG. 8 is a connection wiring diagram illustrating a PFC circuit according to a third embodiment;

FIG. 9 is a connection wiring diagram illustrating a schematic configuration of a power-supply unit according to a fourth embodiment; and

FIG. 10 is a connection wiring diagram illustrating a schematic configuration of a high-frequency amplifier according to a fifth embodiment.

### DESCRIPTION OF EMBODIMENTS

Hereinafter, the embodiments will be described in detail with reference to the accompanying drawings. In the below-described embodiments, a configuration of each compound semiconductor device will be described along with a method for manufacturing the compound semiconductor device.

Note that for convenience of illustration, some components are illustrated not in conformity to the relatively correct sizes and thicknesses thereof in the drawings cited below.

### First Embodiment

The present embodiment discloses a Schottky-type AlGaN/GaN HEMT as a compound semiconductor device.

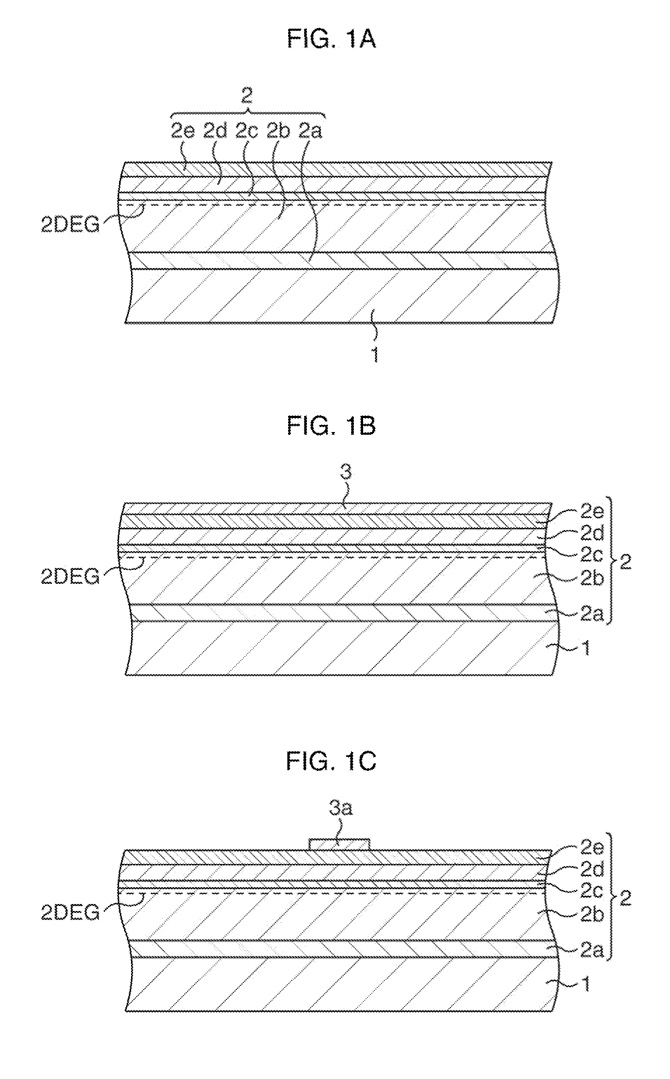

FIGS. 1 to 4 are schematic cross-sectional views illustrating a method for manufacturing the Schottky-type AlGaN/GaN HEMT according to a first embodiment in the order of steps.

First, as illustrated in FIG. 1A, a laminated compound semiconductor structure 2 is formed on, for example, a semi-insulating SiC substrate 1 used as a substrate for growth. As the substrate for growth, a sapphire substrate, a GaAs substrate, an Si substrate, a GaN substrate, or the like may be used in place of the SiC substrate. In addition, the conductive property of a substrate may be of any type, whether semi-insulating or electroconductive.

The laminated compound semiconductor structure 2 includes a nucleation layer 2a, an electron transit layer 2b, an intermediate layer (spacer layer) 2c, an electron supply layer 2d, and a cap layer 2e.

Specifically, the below-described respective compound semiconductors are grown on the SiC substrate 1 by, for example, a metal organic vapor phase epitaxy (MOVPE) method. A molecular beam epitaxy (MBE) method or the like may be used instead of the MOVPE method.

On the SiC substrate 1, the respective compound semiconductors to serve as the nucleation layer 2a, the electron transit layer 2b, the intermediate layer 2c, the electron supply layer 2d, and the cap layer 2e are grown in order. The nucleation layer 2a is formed by growing AlN to a thickness of, for example, approximately 0.1 μm. The electron transit layer 2b is formed by growing i (intentionally undoped)-GaN to a thickness of, for example, approximately 3 μm. The intermediate layer 2c is formed by growing i-AlGaN to a thickness of, for example, approximately 5 nm. The electron supply layer 2d is formed by growing n-AlGaN to a thickness of, for example, approximately 30 nm. The cap layer 2e is formed by growing n-GaN to a thickness of, for example, approximately 10 nm. The intermediate layer 2c is not formed in some cases. The electron supply layer may be formed of i-AlGaN.

For the growth of GaN, a mixed gas composed of a trimethyl gallium (TMGa) gas which is a Ga source and a ammonia (NH₃) gas is used as a raw material gas. For the growth of AlGaN, a mixed gas composed of a trimethyl aluminum (TMAl) gas, a TMGa gas and an NH₃ gas is used as a raw material gas. Whether or not to supply the TMAl gas and/or the TMGa gas is determined and the flow rates of the gases are set as appropriate, according to a compound semiconductor layer to be grown. The flow rate of the NH₃ gas which is a common raw material is set to approximately 100 sccm to 10 slm. In addition, growth pressure is set to approximately 50 Torr to 300 Torr, and growth temperature is set to approximately 1000° C. to 1200° C.

When AlGaN and GaN are grown as n-type semiconductors, i.e., when the electron supply layer 2d (n-AlGaN) and the cap layer 2e (n-GaN) are formed, an n-type impurity is added to the raw material gases of AlGaN and GaN. Here, an Si-containing silane (SiH₄) gas, for example, is added to the raw material gases at a predetermined flow rate, thereby doping GaN and AlGaN with Si. The doping concentration of Si is set to approximately 1×10¹⁸/cm³ to 1×10²⁰/cm³, for example, approximately 5×10¹⁸/cm³.

In the laminated compound semiconductor structure 2 thus formed, piezoelectric polarization caused by strain due to a difference in lattice constant between GaN and AlGaN takes place in the interfacial boundary of the electron transit layer 2b with the electron supply layer 2d (to be precise, the interfacial boundary with the intermediate layer 2c, which will hereinafter be described as the GaN/AlGaN interface). The effect of this piezoelectric polarization, in combination with the effect of spontaneous polarization of the electron transit layer 2b and the electron supply layer 2d, gives rise to a high-electron concentration, two-dimensional electron gas (2DEG) in the GaN/AlGaN interface.

Subsequently, as illustrated in FIG. 1B, a p-type impurity-doped compound layer, an MgO layer 3 here, is film-formed on the laminated compound semiconductor structure 2.

Specifically, MgO is deposited on the laminated compound semiconductor structure 2 by, for example, an evaporation method, to a thickness of approximately 50 nm. This process forms the MgO layer 3 covering the laminated compound semiconductor structure 2.

Subsequently, the MgO layer 3 is processed as illustrated in FIG. 1C.

Specifically, a silicon oxide (SiO₂) is formed on the MgO layer 3 and SiO₂ is processed by lithography to form an SiO₂ mask which covers a portion of the MgO layer 3 where a gate electrode is to be formed, and opens the rest of the MgO layer 3. Using this SiO₂ mask, the MgO layer 3 is wet-etched. Wet etching is performed with the device being fabricated immersed in sulfuric acid. This wet etching removes portions of the MgO layer 3 exposed out of the openings of the SiO₂ mask, thereby causing the MgO layer 3 to remain in the portion of the laminated compound semiconductor structure 2 where the gate electrode is to be formed. The remaining MgO layer 3 is illustrated as an MgO layer 3a. This MgO layer 3a serves as a later-described diffusion source of Mg which is a p-type impurity.

The SiO₂ mask is removed by wet processing, asking treatment, or the like.

MgO is a material which can be wet-etched to apply desired processing thereto. In the present embodiment, the MgO layer 3 is processed by wet etching rather than dry etching. Accordingly, the MgO layer 3a having a desired shape can be obtained without causing any etching damage to the laminated compound semiconductor structure 2.

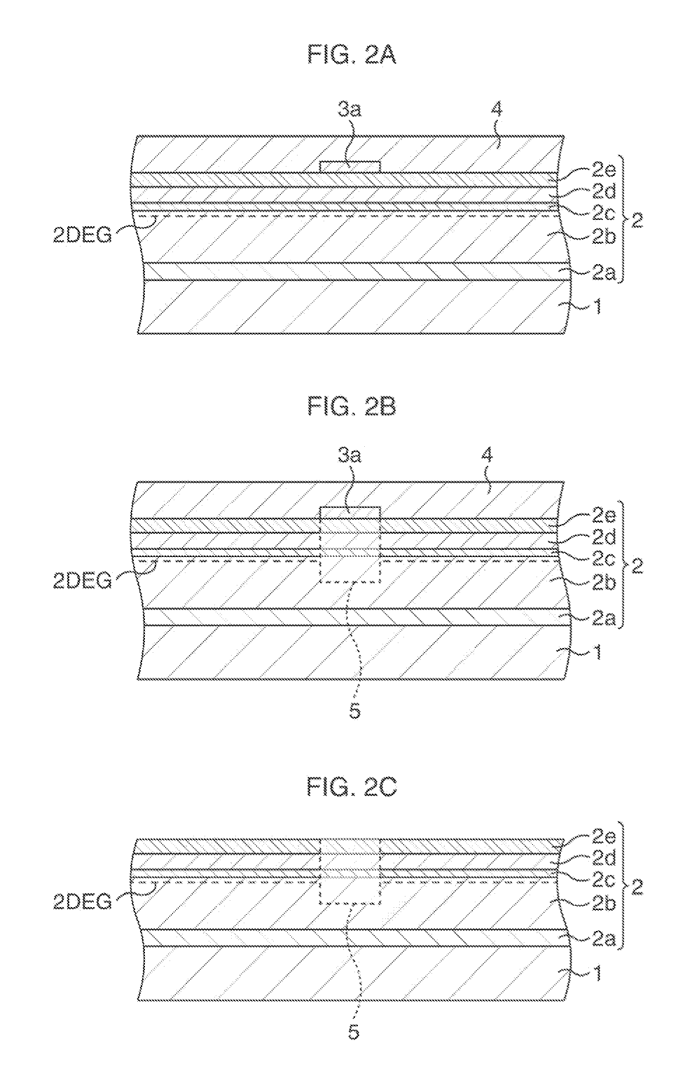

Subsequently, a protective film 4 for covering the MgO layer 3a is formed as illustrated in FIG. 2A.

Specifically, a silicon oxide (SiO₂), for example, is deposited on the laminated compound semiconductor structure 2 by a thermal CVD method or the like to a thickness of approximately 100 nm, so as to cover the MgO layer 3a. This process forms the protective film covering the MgO layer 3a and the cap layer 2e. The protective film 4 is formed in order to protect a surface of GaN.

Subsequently, as illustrated in FIG. 2B, an Mg diffusion region 5 is formed in the laminated compound semiconductor structure 2.

Specifically, the MgO layer 3a is heat-treated through the protective film 4. The heat treatment temperature is 900° C. or higher, for example, approximately 1100° C., and the heat treatment time is approximately 30 minutes. This heat treatment causes Mg which is a p-type impurity to diffuse from the MgO layer 3a into a portion of the laminated compound semiconductor structure 2 underneath the MgO layer 3a. Oxygen (O) also diffuses at this time. Mg and O diffuse, within the range of the laminated compound semiconductor structure 2 in alignment with the MgO layer 3a, from a surface (a surface of the cap layer 2e) of the laminated compound semiconductor structure 2 to a portion thereof including a 2DEG at the GaN/AlGaN interface. This process forms a diffusion region 5 composed of Mg and O (hereinafter simply described as the Mg diffusion region 5) underneath the laminated compound semiconductor structure 2. The Mg diffusion region 5 is where diffused Mg and O localize from a surface of the cap layer 2e to a portion of the electron transit layer 2b including the 2DEG, within the range of the laminated compound semiconductor structure 2 in alignment with the MgO layer 3a. In the Mg diffusion region 5, part of the 2DEG (a portion of the 2DEG, among the portions thereof formed in the GaN/AlGaN interface, in alignment with the MgO layer 3a) is cancelled out by the diffused Mg and, therefore, disappears.

Subsequently, the protective film 4 and the MgO layer 3a are removed as illustrated in FIG. 2C.

The protective film 4 and the MgO layer 3a on the laminated compound semiconductor structure 2 are removed by wet etching. The Mg diffusion region 5 remains in the laminated compound semiconductor structure 2. The protective film 4 and the MgO layer 3a can be etched away using hydrofluoric acid and sulfuric acid, respectively, as etchants in wet etching.

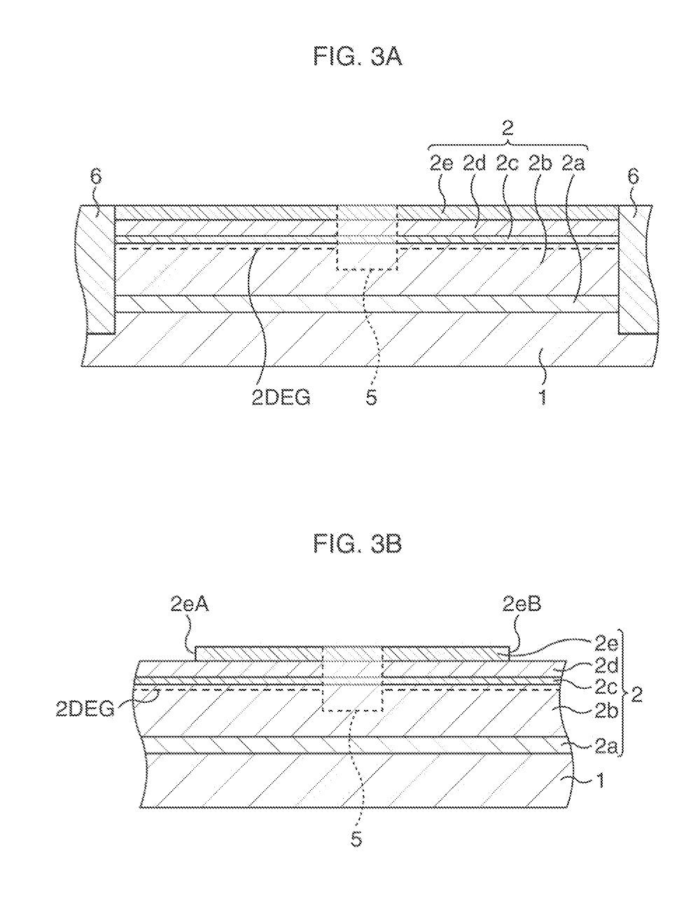

Subsequently, an element isolation structure 6 is formed as illustrated in FIG. 3A. In FIG. 3B and subsequent figures, the element isolation structure 6 will be excluded from illustrations.

Specifically, argon (Ar), for example, is implanted in an element-isolating region of the laminated compound semiconductor structure 2. This process forms the element isolation structure 6 in the laminated compound semiconductor structure 2 and in a surface layer part of the SiC substrate 1. Thus, the element isolation structure 6 defines an active region on the laminated compound semiconductor structure 2.

Note that element isolation may be performed using another known method, for example, an STI (Shallow Trench Isolation) method, instead of the above-described implantation method. At this time, a chlorine-based etching gas, for example, is used for the dry etching of the laminated compound semiconductor structure 2.

Subsequently, openings 2eA and 2eB for electrode formation are formed in the cap layer 2e, as illustrated in FIG. 3B.

Specifically, a resist is first coated on a surface of the laminated compound semiconductor structure 2. Then, the resist is processed by lithography to form openings to expose therein surface parts of the laminated compound semiconductor structure 2 where source and drain electrodes are to be formed. This process forms a resist mask having the abovementioned openings.

Using this resist mask, the cap layer 2e is dry-etched until a surface of the electron supply layer 2d becomes exposed. This process forms, in the cap layer 2e, the openings 2eA and 2eB to expose therein surface parts of the electron supply layer 2d where source and drain electrodes are to be formed. In dry etching, an inert gas, such as Ar, and a chlorine-based gas, such as Cl₂, are used as etching gases. Note that the openings 2eA and 2eB may be formed by etching the cap layer 2e halfway therethrough or by etching the laminated compound semiconductor structure 2 to a predetermined depth beyond the electron supply layer 2d.

The resist mask is removed by wet treatment, asking treatment, or the like.

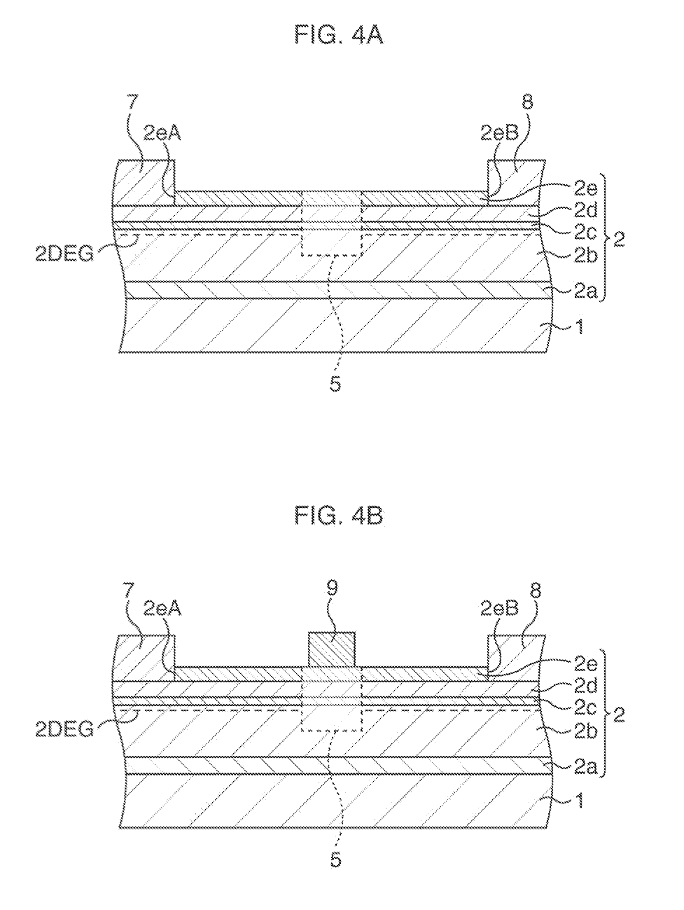

Subsequently, a source electrode 7 and a drain electrode 8 are formed as illustrated in FIG. 4A.

First, a resist mask for forming the source and drain electrodes is formed. Here, an eaves-structured two-layer resist suited for an evaporation method and a liftoff method, for example, is used.

This resist is coated on the laminated compound semiconductor structure 2 to form openings to expose therein the openings 2eA and 2eB. This process forms the resist mask having the abovementioned openings.

Using this resist mask, Ta and Al, for example, is deposited as an electrode material by, for example, an evaporation method on the resist mask, including the interiors of the openings 2eA and 2eB. The thickness of Ta is set to approximately 20 nm, and the thickness of Al is set to approximately 200 nm. The resist mask and Ta and Al deposited thereon are removed by a liftoff method. Thereafter, the SiC substrate 1 is heat-treated in, for example, a nitrogen atmosphere at a temperature of 400° C. to 1000° C., for example, at approximately 550° C., thereby causing remaining Ta and Al to have ohmic contact with the electron supply layer 2d. Heat treatment may not be necessary as long as the ohmic contact of Ta and Al with the electron supply layer 2d is available. This process forms the source electrode 7 and the drain electrode 8 in which the openings 2eA and 2eB are filled with part of the electrode material.

Subsequently, a gate electrode 9 is formed as illustrated in FIG. 4B.

Specifically, a resist mask for forming the gate electrode is formed first. Here, an eaves-structured two-layer resist suited for an evaporation method and a liftoff method, for example, is used. This resist is coated on the laminated compound semiconductor structure 2 to form an opening to expose therein a surface of the Mg diffusion region 5 of the cap layer 2e. This process forms the resist mask having the abovementioned opening.

Using this resist mask, Ni and Au, for example, is deposited as an electrode material by, for example, an evaporation method on the resist mask, including the interiors of the opening to expose therein the surface of the Mg diffusion region 5. The thickness of Ni is set to approximately 30 nm, and the thickness of Au is set to approximately 400 nm. The resist mask and Ni and Au deposited thereon are removed by a liftoff method. This process forms the gate electrode 9 on the Mg diffusion region 5 of the cap layer 2e.

Thereafter, a Schottky-type AlGaN/GaN HEMT according to the present embodiment is formed after being made to go through steps, including a step of forming wiring lines to be connected to the source electrode 7, the drain electrode 8, and the gate electrode 9.

As has been described heretofore, in the present embodiment, the MgO layer 3a is used as a diffusion source of Mg which is a p-type impurity. The Mg is diffused by heat treatment to form the Mg diffusion region 5 which localizes in an area underneath the gate electrode 9 in the laminated compound semiconductor structure 2. The 2DEG in the GaN/AlGaN interface disappears only in a portion of the Mg diffusion region 5 in alignment with the gate electrode 9. This configuration pushes up an energy band immediately underneath the gate electrode 9, thereby realizing reliable normally-off operation.

In addition, in the present embodiment, wet etching is used when the MgO layer 3 is processed by etching to leave the MgO layer 3a in a portion of the MgO layer 3 where the gate electrode is to be formed. Accordingly, unlike in the case of using dry etching, no etching damage is caused to the laminated compound semiconductor structure 2. Thus, the present embodiment realizes a high-quality, high-reliability normally-off AlGaN/GaN HEMT.

### Second Embodiment

The present embodiment discloses an MIS (Metal-Insulator-Semiconductor)-type AlGaN/GaN HEMT as a compound semiconductor device.

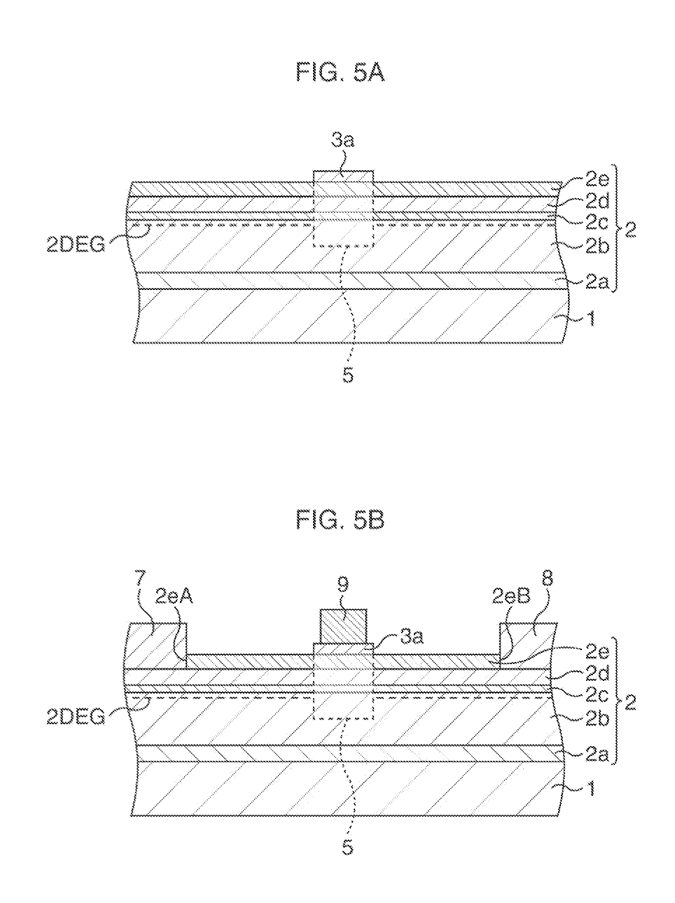

FIGS. 5A and 5B are schematic cross-sectional views illustrating main steps of a method for manufacturing an MIS-type AlGaN/GaN HEMT according to the second embodiment. Note that the same components and the like as those of the first embodiment are denoted by like reference numerals and characters and will be described in no further detail here.

First, the steps of FIGS. 1A to 2B are carried out in order in the same way as in the first embodiment. The step of FIG. 2A forms the Mg diffusion region 5 in the laminated compound semiconductor structure 2.

Subsequently, the protective film 4 is removed as illustrated in FIG. 5A.

Specifically, a portion of the protective film 4 on the laminated compound semiconductor structure 2 is removed by wet etching. The Mg diffusion region 5 and the MgO layer 3a thereon remain in the laminated compound semiconductor structure 2. With wet etching, only the protective film 4 can be removed using hydrofluoric acid as an etching liquid, while leaving over the MgO layer 3a. The remaining MgO layer 3a is used as a gate insulating film, as will be described later.

Subsequently, the steps of FIGS. 3A to 4A are carried out in order in the same way as in the first embodiment. The step of FIG. 3B forms the source electrode 7 and the drain electrode 8 in the laminated compound semiconductor structure 2.

Subsequently, a gate electrode 9 is formed as illustrated in FIG. 5B.

Specifically, a resist mask for forming the gate electrode is formed first. Here, an eaves-structured two-layer resist suited for an evaporation method and a liftoff method, for example, is used. This resist is coated on the laminated compound semiconductor structure 2 to form an opening to expose therein a surface of the MgO layer 3a. This process forms the resist mask having the abovementioned opening.

Using this resist mask, Ni and Au, for example, is deposited as an electrode material by, for example, an evaporation method on the resist mask, including the interiors of the opening to expose therein the surface of the MgO layer 3a. The thickness of Ni is set to approximately 30 nm, and the thickness of Au is set to approximately 400 nm. The resist mask and Ni and Au deposited thereon are removed by a liftoff method. This process forms the gate electrode 9 on the MgO layer 3a. The MgO layer 3a functions as a gate insulating film.

Note that in the first embodiment, a case has been cited in which the MgO layer 3 is formed to a thickness of approximately 50 nm in the step of FIG. 1B. In the present embodiment, however, the MgO layer 3a used as a diffusion source is also used as a gate insulating film. Accordingly, the MgO layer 3 may be formed to a thickness best suited for the gate insulating film, i.e., to a thickness of approximately 10 nm to 100 nm here, for example, approximately 20 nm.

Thereafter, an MIS-type AlGaN/GaN HEMT according to the present embodiment is formed after being made to go through steps, including a step of forming wiring lines to be connected to the source electrode 7, the drain electrode 8, and the gate electrode 9.

As has been described heretofore, in the present embodiment, the MgO layer 3a is used as a diffusion source of Mg which is a p-type impurity. The Mg is diffused by heat treatment to form the Mg diffusion region 5 which localizes in an area underneath the gate electrode 9 in the laminated compound semiconductor structure 2. In the Mg diffusion region 5, a 2DEG of the electron transit layer 2b disappears within the range of the laminated compound semiconductor structure 2 in alignment with the gate electrode 9. This configuration pushes up an energy band immediately underneath the gate electrode 9, thereby realizing reliable normally-off operation.

In addition, in the present embodiment, wet etching is used when the MgO layer 3 is processed by etching to leave the MgO layer 3a in a portion of the MgO layer 3 where the gate electrode is to be formed. Accordingly, unlike in the case of using dry etching, no etching damage is caused to the laminated compound semiconductor structure 2. Thus, the present embodiment realizes a high-quality, high-reliability normally-off AlGaN/GaN HEMT.

Yet additionally, in the present embodiment, the MgO layer 3a is also used as a gate insulating film without being removed, after the MgO layer 3a is used as a diffusion source of Mg. This configuration eliminates the step of forming a gate insulating film and can reduce manufacturing costs.

Note that the range of options for the gate insulating film can be expanded to form a desired gate insulating film separately from the MgO layer 3a. In this case, an insulating film to serve as the gate insulating film is formed on the laminated compound semiconductor structure 2, after the steps of FIG. 1A to FIG. 2C of the first embodiment are carried out in order and the MgO layer 3a is removed along with the protective film 4. The gate electrode 9 is formed on the gate insulating film. For the material of the insulating film, a nitride or oxynitride of Al₂O₃ or Al is used. In addition to these materials, an oxide, nitride or oxynitride of Si, Hf, Zr, Ti, Ta or W may be used. Alternatively, materials may be selected as appropriate from these options and deposited into multiple layers, thereby forming the gate insulating film.

In the first and second embodiments, a case has been cited in which MgO is used as a diffusion source of a p-type impurity to form the MgO layer 3. The diffusion source is not limited to MgO, however. Alternatively, another p-type impurity compound may be formed as a source of diffusion. For example, it is conceivable to use BeO as a diffusion source of a p-type impurity. In this case, a BeO film deposited on the laminated compound semiconductor structure 2 is patterned so as to leave the BeO film in a portion of the laminated compound semiconductor structure 2 where a gate electrode is to be formed. Then, Be is diffused by heat treatment from the remaining BeO film to the underlying the laminated compound semiconductor structure 2. Be diffuses from a surface (a surface of the cap layer 2e) to a portion of the laminated compound semiconductor structure 2 including the 2DEG of the electron transit layer 2b, within the range of the laminated compound semiconductor structure 2 in alignment with the BeO film thereof. In the same way as the Mg diffusion region 5 is formed, this process forms a Be diffusion region which localizes in an area underneath the gate electrode 9 on the laminated compound semiconductor structure 2. In the Be diffusion region, the 2DEG of the electron transit layer 2b disappears within the range of the laminated compound semiconductor structure 2 in alignment with the gate electrode 9, thereby realizing reliable normally-off operation.

The AlGaN/GaN HEMT according to the first or second embodiment is applied to a so-called discrete package.

A chip of the AlGaN/GaN HEMT according to the first or second embodiment is mounted on this discrete package. Hereinafter, a discrete package of the chip of the AlGaN/GaN HEMT according to the first or second embodiment (hereinafter referred to as the HEMT chip) will be described by way of example.

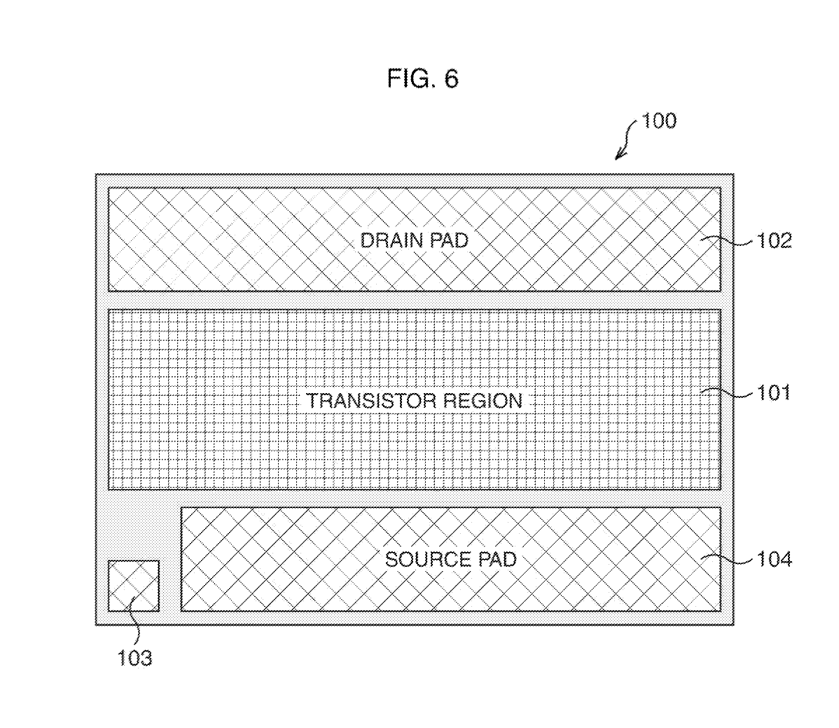

FIG. 6 illustrates a schematic configuration of the HEMT chip.

A transistor region 101 of the above-mentioned AlGaN/GaN HEMT, a drain pad 102 to which a drain electrode is connected, a gate pad 103 to which a gate electrode is connected, and a source pad 104 to which a source electrode is connected are provided on a surface of a HEMT chip 100.

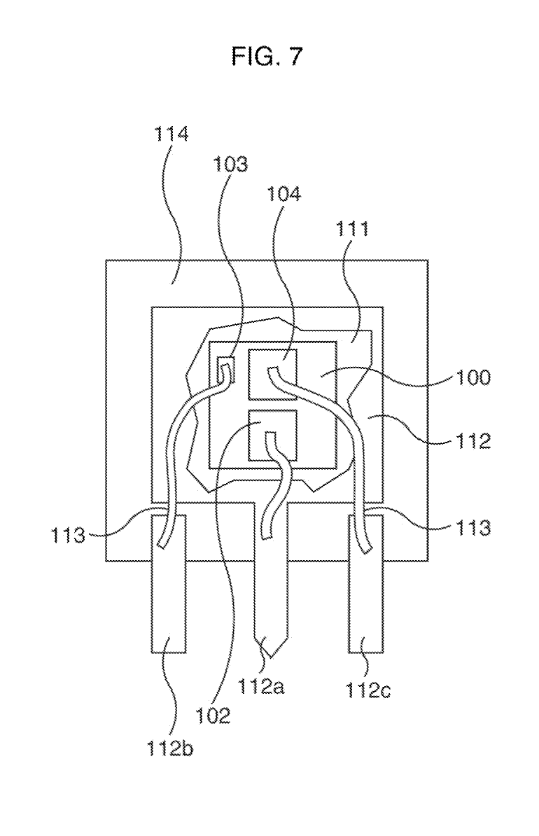

FIG. 7 is a schematic plan view illustrating the discrete package.

In order to fabricate the discrete package, the HEMT chip 100 is first fixed to a lead frame 112 by using a die attach agent 111, such as solder. A drain lead 112a is formed integrally with the lead frame 112, and a gate lead 112b and a source lead 112c are arranged separately and away from the lead frame 112.

Subsequently, the drain pad 102 and the drain lead 112a, the gate pad 103 and the gate lead 112b, and the source pad 104 and the source lead 112c are electrically connected to each other, respectively, by bonding using an Al wire 113.

Thereafter, the HEMT chip 100 is resin-sealed by a transfer molding method using molding resin 114, and the lead frame 112 is cut off. This process forms the discrete package.

### Third Embodiment

The present embodiment discloses a PFC (Power Factor Correction) circuit provided with one type of AlGaN/GaN HEMT selected from those of the first and second embodiments.

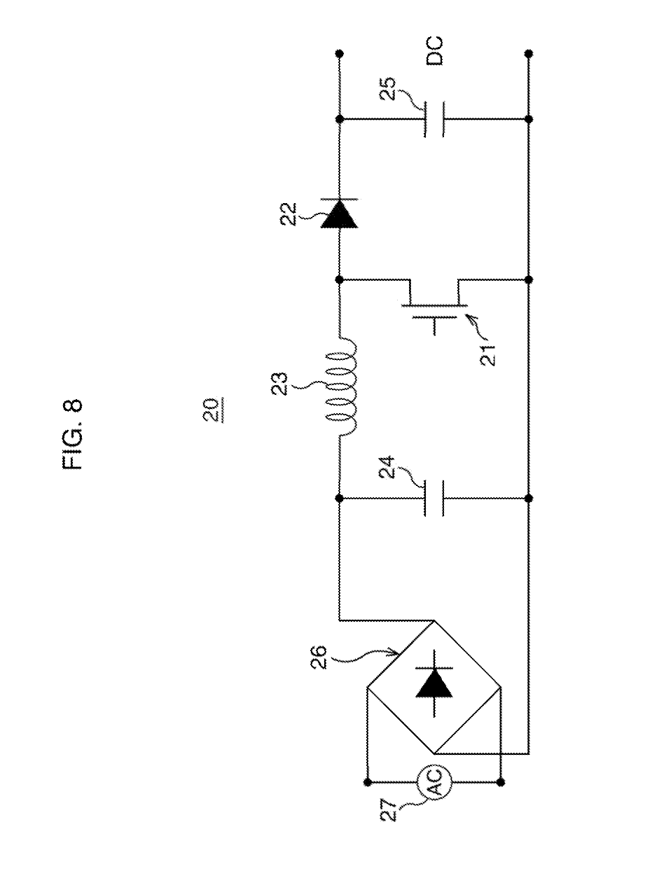

FIG. 8 is a connection wiring diagram illustrating the PFC circuit.

A PFC circuit 20 is provided with a switch element (transistor) 21, a diode 22, a choke coil 23, a capacitor 24, 25, a diode bridge 26, and an AC power supply (AC) 27. One type of AlGaN/GaN HEMT selected from those of the first and second embodiments is applied to the switch element 21.

In the PFC circuit 20, the drain electrode of the switch element 21 is connected to the anode terminal of the diode 22 and one terminal of the choke coil 23. The source electrode of the switch element 21 is connected to one terminal of the capacitor 24 and one terminal of the capacitor 25. The other terminal of the capacitor 24 and the other terminal of the choke coil 23 are connected to each other. The other terminal of the capacitor 25 and the cathode terminal of the diode 22 are connected to each other. The AC 27 is connected between the two terminals of the capacitor 24 through the diode bridge 26. A DC power source (DC) is connected between the two terminals of the capacitor 25. Note that an unillustrated PFC controller is connected to the switch element 21.

In the present embodiment, one type of AlGaN/GaN HEMT selected from those of the first and second embodiments is applied to the PFC circuit 20. This configuration realizes a high-reliability PFC circuit 30.

### Fourth Embodiment

The present embodiment discloses a power-supply unit provided with one type of AlGaN/GaN HEMT selected from those of the first and second embodiments.

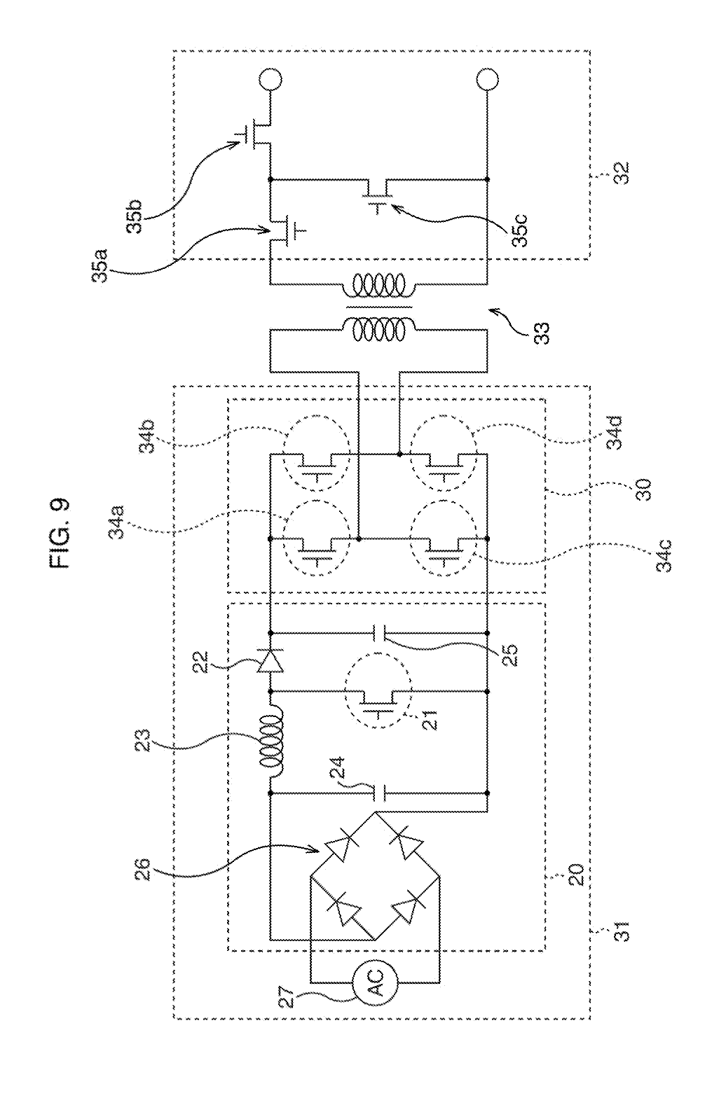

FIG. 9 is a connection wiring diagram illustrating a schematic configuration of a power-supply unit according to the fourth embodiment.

The power-supply unit according to the present embodiment is provided with a high-voltage primary-side circuit 31, a low-voltage secondary-side circuit 32, and a transformer 33 arranged between the primary-side circuit 31 and the secondary-side circuit 32.

The primary-side circuit 31 includes a PFC circuit 20 according to the third embodiment, and an inverter circuit, for example, a full-bridge inverter circuit 30 connected between the two terminals of the capacitor 25 of the PFC circuit 50. The full-bridge inverter circuit 30 is provided with a plurality of (four, here) switch elements 34a, 34b, 34c and 34d.

The secondary-side circuit 32 is provided with a plurality of (three, here) switch elements 35a, 35b and 35c.

In the present embodiment, the PFC circuit constituting the primary-side circuit 31 is specified as the PFC circuit 20 according to the third embodiment, and the switch elements 34a, 34b, 34c and 34d of the full-bridge inverter circuit 30 are specified as one type of AlGaN/GaN HEMT selected from those of the first and second embodiments. On the other hand, the switch elements 35a, 35b and 35c of the secondary-side circuit 32 are specified as regular MIS FETs using silicon.

In the present embodiment, the PFC circuit according to the third embodiment and one type of AlGaN/GaN HEMT selected from those of the first and second embodiments are applied to the primary-side circuit 31 which is a high-voltage circuit. This configuration realizes a high-reliability high-output power-supply unit.

### Fifth Embodiment

The present embodiment discloses a high-frequency amplifier provided with one type of AlGaN/GaN HEMT selected from those of the first and second embodiments.

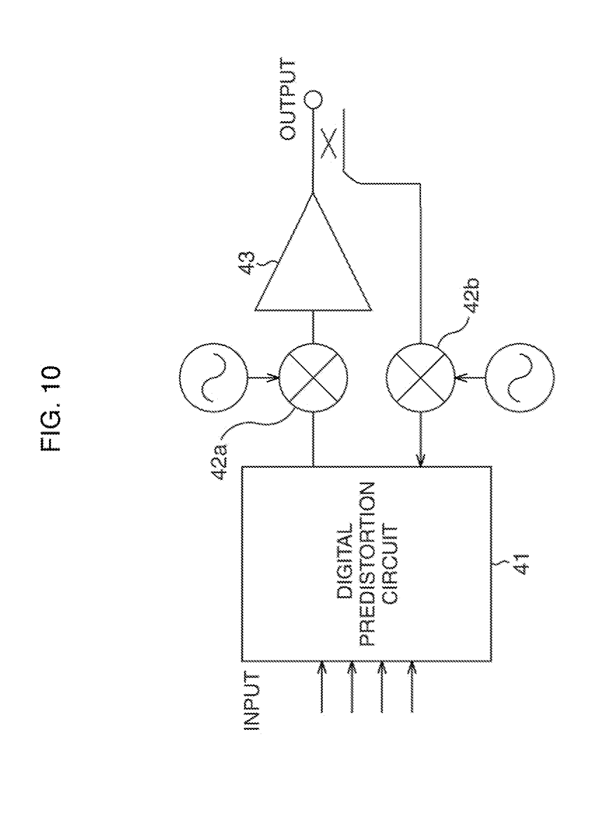

FIG. 10 is a connection wiring diagram illustrating a schematic configuration of a high-frequency amplifier according to the fifth embodiment.

The high-frequency amplifier according to the present embodiment is provided with a digital predistortion circuit 41, mixers 42a and 42b, and a power amplifier 43.

The digital predistortion circuit 41 compensates for the nonlinear distortions of an input signal. The mixer 42a mixes the input signal compensated for nonlinear distortions and an AC signal. The power amplifier 43 amplifies the input signal mixed with the AC signal, and includes one type of AlGaN/GaN HEMT selected from those of the first and second embodiments. Note that in FIG. 10, the high-frequency circuit is configured to be able to mix an output-side signal with the AC signal by the mixer 42b and send out the mixed signal to the digital predistortion circuit 41 by means of, for example, switch operation.

In the present embodiment, one type of AlGaN/GaN HEMT selected from those of the first and second embodiments is applied to the high-frequency amplifier. This configuration realizes a high-reliability, highly voltage-resistant high-frequency amplifier.

### Other Embodiments

In the first and second embodiments, an AlGaN/GaN HEMT has been cited, by way of example, as a compound semiconductor device. As compound semiconductor devices, the embodiments can also be applied to the below-described HEMTs, in addition to the AlGaN/GaN HEMT.

Example 1 of Other Devices

The present example discloses an InAlN/GaN HEMT as a compound semiconductor device.

InAlN and GaN are compound semiconductors the lattice constants of which can be approximated to each other by means of composition. In this case, an electron transit layer, an intermediate layer, an electron supply layer and a cap layer are formed of i-GaN, AlN, n-InAlN and n-GaN, respectively, in the above-described first and second embodiments. In addition, a two-dimensional electron gas is generated mainly by the spontaneous polarization of InAlN since piezoelectric polarization hardly occurs in this case.

According to the present example, there is realized a high-reliability InAlN/GaN HEMT, like the above-described AlGaN/GaN HEMT, capable of realizing reliable normally-off operation without causing any damage to a laminated compound semiconductor structure.

Example 2 of Other Devices

The present example discloses an InAlGaN/GaN HEMT as a compound semiconductor device.

GaN and InAlGaN are compound semiconductors in which the lattice constant of GaN can be made smaller than that of InAlGaN by means of composition. In this case, an electron transit layer, an intermediate layer, an electron supply layer and a cap layer are formed of i-GaN, i-InAlGaN, n-InAlGaN and n-GaN, respectively, in the above-described first and second embodiments.

According to the present example, there is realized a high-reliability InAlN/GaN HEMT, like the above-described AlGaN/GaN HEMT, capable of realizing reliable normally-off operation without causing any damage to a laminated compound semiconductor structure.

According to the above-described respective aspects of the embodiments, there is realized a high-reliability compound semiconductor device capable of realizing reliable normally-off operation without causing any damage to a laminated compound semiconductor structure.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A compound semiconductor device, comprising:
a laminated compound semiconductor structure; and
an electrode formed on the laminated compound semiconductor structure,
wherein a p-type impurity localizes in a lower region of the laminated compound semiconductor structure aligned with the electrode, to such a depth as to cause part of a two-dimensional electron gas generated in the laminated compound semiconductor structure to disappear.

2. The compound semiconductor device according to claim 1, wherein the p-type impurity and oxygen localize in the lower region of the laminated compound semiconductor structure aligned with the electrode, to such a depth as to cause part of a two-dimensional electron gas generated in the laminated compound semiconductor structure to disappear.

3. The compound semiconductor device according to claim 1, further comprising an insulating film formed between the laminated compound semiconductor structure and the electrode.

4. The compound semiconductor device according to claim 3, wherein the insulating film is a compound layer of the p-type impurity used as a thermal diffusion source of the p-type impurity.

5. The compound semiconductor device according to claim 1, wherein the p-type impurity is one of Mg and Be.

6. A method for manufacturing a compound semiconductor device, the method comprising:
forming a p-type impurity-doped compound layer in a region on a laminated compound semiconductor structure where an electrode is to be formed; and
heat-treating the compound layer to diffuse the p-type impurity of the compound layer to such a depth as to cause part of a two-dimensional electron gas generated in the laminated compound semiconductor structure to disappear.

7. The method for manufacturing a compound semiconductor device according to claim 6, wherein the compound layer formed so as to cover an upper portion of the laminated compound semiconductor structure is wet-etched to leave the compound layer in the region where an electrode is to be formed.

8. The method for manufacturing a compound semiconductor device according to claim 6, wherein a protective film is formed so as to cover the compound layer, and the heat treatment is performed with the compound layer covered with the protective film.

9. The method for manufacturing a compound semiconductor device according to claim 6, further comprising:
subsequent to the heat treatment, removing the compound layer; and
forming a gate electrode in the region where an electrode is to be formed.

10. The method for manufacturing a compound semiconductor device according to claim 6, further comprising:
subsequent to the heat treatment, forming a gate electrode on the compound layer.

11. The method for manufacturing a compound semiconductor device according to claim 6, wherein the p-type impurity is one of Mg and Be.

12. A power-supply unit comprising a transformer, and a high-voltage circuit and a low-voltage circuit with the transformer therebetween, wherein the high-voltage circuit includes a transistor including:
a laminated compound semiconductor structure; and
an electrode formed on the laminated compound semiconductor structure,
wherein a p-type impurity localizes in a lower region of the laminated compound semiconductor structure aligned with the electrode, to such a depth as to cause part of a two-dimensional electron gas generated in the laminated compound semiconductor structure to disappear.
